(19) United States
(12) Patent Application Publication
(10) Pub. No.: US 2016/0154301 A1
(43) Pub. Date: Jun. 2, 2016

(54) SCANNING COHERENT DIFFRACTIVE IMAGING METHOD AND SYSTEM FOR ACTINIC MASK INSPECTION FOR EUV LITHOGRAPHY

(71) Applicant: PAUL SCHERRER INSTITUT, Villigen PSI (CH)

(72) Inventor: YASIN EKINCI, ZUERICH (CH)

(21) Appl. No.: 14/899,235

(22) PCT Filed: May 26, 2014
(86) PCT No.: PCT/EP2014/060834

§ 371 Date: Dec. 17, 2015

(30) Foreign Application Priority Data
Jun. 17, 2013 (EP) 13172238.1

(51) Int. Cl. G03F 1/84

(52) U.S. Cl. CPC G03F 1/84

(57) ABSTRACT

Reflective and scanning CDI for identifying errors in mask patterns and defects on mask blanks. Providing a set-up for scanning the mask in reflection mode with low and/or high NA. Illuminating the mask pattern with EUV light at 2 to 35°. Detecting the diffracted light beam with a position sensitive detector. Analyzing the detected intensities using ptychographic algorithms and thereby obtaining a high resolution image of the sample of arbitrary patterns. Analyzing the detected intensities for intensity variations deviating from the normal intensity distribution caused by the periodic mask pattern in order to detect defects on the mask. This novel technique may be referred to as differential CDI. For periodically structured masks, a fast inspection can be executed by steps of multiples of period, which should give the same diffraction pattern. The investigation for only the deviation from the normal diffraction pattern allows rapid identification of periodic mask pattern defects.

The present invention relates to a scanning coherent diffractive imaging method and system for actinic mask inspection for EUV lithography.

EUV lithography is the most promising route to face challenges of the semiconductor industry for high-volume manufacturing at the technology nodes of 22 nm and below. One of the major challenges of the EUV lithography is the masks with low defect density. Therefore, tools for sensitive and rapid identification and characterization of defects on mask blanks and patterned masks are of great importance. Although different metrology tools such as SEM, AFM, and DUV microscopes, provide some information, actinic inspection, i.e. inspection with EUV light, enables the true characterization of the defects. Currently, there is a great and immediate need for such tools. There are two types of defects on EUV masks, namely amplitude and phase defects. The defects on the multilayer are mainly amplitude defects whereas the ones under the multilayer are purely phase defects. The defects within the multilayer lead to both phase and amplitude modulation.

There are two types of samples:
i) One is mask blanks, i.e, substrates coated with multilayers on which defects with very low density (ideally less than a few defects per cm²) are present. The aims of inspection tasks may be different such as determination of defect density of mask blanks, identification of the defects (phase, amplitude, size, type of defect), comparison of defect density of blanks which went through different preparation or cleaning process, evaluation of a certain cleaning process if it is successful for removal of a previously identified defect, etc.
ii) The other one is the patterned masks on which the required patterns are written as absorber structures on mask blanks. The feature size of the patterns is 4× larger than the desired pattern on wafer. This means, for instance, for 11 nm technology node the minimum feature size will be 44 nm.

By inspection we mean metrology methods for mask review/inspection/characterization/evaluation of the masks to be used for lithography. The aims include, but not limited to, obtaining the areal image of the mask, identification of the defects and their characterization. By actinic inspection we mean at wavelength and relevant incidence angle of the light. For EUV mask, this must be reflective and at incidence angle of 6 degrees at 13.5 nm wavelength. This is the standard condition for the use of the masks in real operation, i.e lithographic production of semiconductor devices.

For an inspection tool following features or aspects are important:
1) Resolution is critical in order to resolve all the defects that contribute to the patterning in the lithographic process and thereby deteriorate the yield in fabrication process. On the other hand, for practical applications, it might be sufficient just to locate the defect, which may not require such a high resolution. For some purpose, even higher resolution might be necessary. For instance, to investigate the effects of line-edge roughness and tiny defects.
2) Throughput is the most important parameter in practical applications. Since the mask sizes are relatively large (>100 mm²), fact identification of defects with nanometer resolution is a great challenge. Since the detection is generally done with a CCD, a detector-limited throughput can be defined: Namely collection time from a spot size (resolution×pixel number) takes less than the read-out time.
3) Characterization of the defects. Sensitivity to certain type of defects, signal-to-noise, independent characterization of amplitude and phase defects are among the issues one should consider.
4) Navigation and flexibility. Fast navigation, exact location of the defects with respect to alignment markers, easy switching between the options of different throughput and resolution are also as important as other parameters.
5) Moreover, cost of ownership, cost of maintenance, reliability, up time are also important aspects.

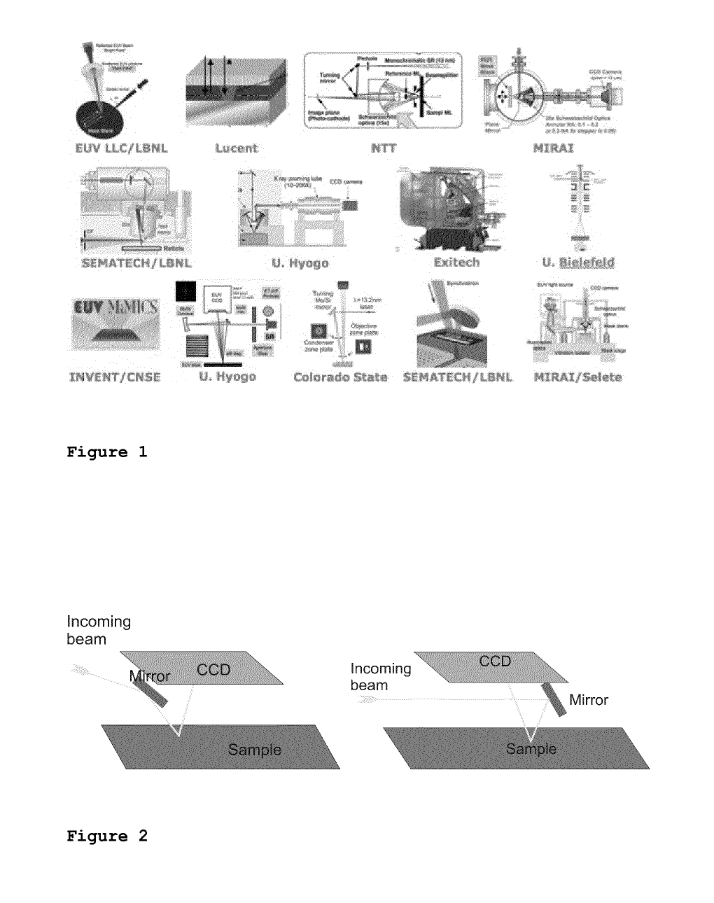

There are tens of EUV actinic mask inspection tools or projects worldwide. An overview of some is shown in FIG. 1. A recent review of the tools is provided in [1]. The tools differ in concepts, purpose, source, detection, and optics. In this document, only Berkeley tool, Zeiss tool and coherent imaging tools will be discussed. Therefore, the present invention should be compared to these tools as a reference for better understanding of the usefulness and impact of the present invention.

Berkeley tool is the leading academic tool. The existing tool is called AIT [2] and the future tool, which will be installed within next year, is called AIT 5 [3]. This tool uses and off-axis FZP up to 0.5 NA. It enables switching the NA and magnification with an ultimate resolution of 26 nm. But this value seems to be too optimistic, given the facts on the difficulty of the method and FZP fabrication.

Zeiss tool (AIMS), which is under construction and most of its details are not disclosed yet, is thought for commercial use. It will use a reflective optics with 0.35 NA. The optics of the tool is highly challenging and sophisticated.

The Kinoshita group working at the New Subaru, is the leading group in CDI based EUV mask inspection. In addition to EUV microscope [4] they are also working on CDI methods [5]. There, it has been already demonstrated CD analysis of simple gratings with low NA with a CDI method. They are also working on a high NA setup. The difficulty as will be discussed above. They have no publication on their future plans, but some information could be found indicating that this year a CDI tool will be available to analyze point defects down to 16 nm (on wafer). Ahn's group in Hanyang University is also developing a CDI tool [6]. Both Japanese and Korean groups have an extensive EUV program, and CDI imaging is only a part of their EUV imaging projects.

It is therefore the object of the present invention to provide a method and a system that allow analyze the structure of period mask for mask error using a rather simple set-up having a sufficient throughput.

This aim is achieved according to the present invention by a method for reflective and scanning CDI for the identification of errors in mask patterns and defects on mask blanks, comprising the steps of:
a) providing a set-up for scanning the mask in reflection mode with low and high NA;
b) illumination the mask pattern with a EUV light beam under an angle of 2 to 35°;
c) detecting the diffracted light beam with a position sensitive detector;
d) analyzing the detected intensities using ptychographic algorithms and thereby obtaining a high resolution image of the sample of arbitrary patterns; and
e) analyzing the detected intensities for intensity variations deviating from the normal intensity distribution caused by the periodic mask pattern in order to detect defects on the mask.

With respect to the system this aim is achieved according to the present invention by a system for differential CDI for the identification of errors in periodic mask patterns, comprising:
a) a ptychographic set-up for scanning the mask pattern;
b) a EUV light beam for illuminating the mask pattern with under an angle of 2 to 35°;
c) a position sensitive detector for detecting the diffracted light beam; and
d) means for analyzing the detected intensities for intensity variations deviating from the normal intensity distribution caused by the periodic mask pattern.

The present invention therefore proposes a novel techniques for lensless, high-resolution and reflective imaging of samples using scanning CDI; as well as detecting the defects by analyzing the detected intensities by looking at their difference from the expected intensities, which can be called differential CDI.

Compared to other lensless imaging methods, in this method a priori knowledge of the illumination is not needed, the sample area is not limited, a reference beam or a reference structure is not needed. Compared to the imaging methods with optics, both amplitude and phase are extracted simultaneously with a 2D scan whereas optics-based imaging requires through-focus, i.e. 3D scan, in order to reconstruct the phase. Moreover, depth of focus is not critical compared to imaging with optics.

For periodically structured masks, a fast inspection can be executed by steps of multiples of period, which should give the same diffraction pattern. Subject of the present invention is that the investigation for only deviation from the normal diffraction pattern will allow rapid identification of the defects on periodic mask patterns. We call this method as differential CDI.

The present invention and its preferred embodiment are hereinafter described in more detail with reference to the attached drawings which depict in:

FIG. 1 shows a number of EUV actinic mask inspection tools according to the prior art; and

FIGS. 2 to 6 show different set-ups of reflective scanning CDI, i.e. ptychographic imaging.

Ptychography is a technique that aims to solve the diffraction-pattern phase problem by interfering adjacent Bragg reflections coherently and thereby determine their relative phase. In the original formulation, it was envisaged that such interference could be effected by placing a very narrow aperture in the plane of the specimen so that each reciprocal-lattice point would be spread out and thus overlap with one another. The name ptychography, from the Greek for fold, derives from this optical configuration; each reciprocal lattice point is convolved with some function, and thus made to interfere with its neighbors. In fact, measuring only the intensities of interfering adjacent diffracted beams still leads to an ambiguity of two possible complex conjugates for each underlying complex diffraction amplitude. The original formulation of ptychography is equivalent to the well known theorem that for a finite specimen (that is one delineated by a narrow aperture, sometimes known as a finite support), the one dimensional phase problem is soluble to within an ambiguity of 2N, where N is the number of Fourier components that make up the specimen. However, such ambiguities may be resolved by changing the phase, profile or position of the illuminating beam in some way. The fact that not only the intensities of the diffracted beams but also the intensities lying midway between the beams, where the convolved Bragg beams interfere, is an alternative statement of the Nyquist-Shannon sampling theorem for components of diffracted intensity. These components generally have twice the frequency (in reciprocal space) of their underlying complex amplitudes.

Ptychographic imaging along with advances in detectors and computing have resulted in X-ray microscopes, optical and electron microscopy with increased spatial resolution without the need for lenses.

Therefore, Ptychography is a CDI method based on scanning with oversampling. It enables high-resolution imaging without optics. It provides both amplitude and phase information of the specimens. Since this method is a coherent imaging method, it has stringent requirements on spatial and temporal coherence. The resolution is limited by the NA of the detector and accuracy of the stage. With high-NA Fourier transform imaging 90 nm resolution has been demonstrated [7] at a wavelength of 29 nm. The resolution was improved by using an iterative phase retrieval method down to 50 nm.

The present invention shows the potential of ptychographic methods for high-resolution imaging in EUV and soft X-ray range.

In principle, ptychography can be used for EUV mask inspection. Following advantages can be listed:

1. Resolution is not limited with optics: detector limited resolution for spot size is possible. High NA EUV optics is vey expensive, making high-resolution inspection tools costly.

2. Throughput (spot size) is not limited with optics (sweet spot, aplanarity). In principle detector limited throughput can be possible, i.e. the time budget is mainly consumed by read-out time of the detector and collection time is insignificant.

3. Depth of focus is not critical.

4. Both amplitude and phase information is obtained. This is particularly important for EUV masks, because the phase defects are difficult to obtain. Phase information can be obtained using optics and through-focus scans. This however reduces the throughput of the imaging, which is very important for EUV mask metrology.

5. It is advantageous over other holographic methods. Since it does not require a priori knowledge of the illumination or reference beam or reference frame/pattern in order to reconstruct the image. Therefore, it is more flexible and imaging area is not limited.

The present invention proposes also a novel technique, which can be called differential CDI. For periodically structured masks, a fast inspection can be executed by steps of multiples of period, which should give the same diffraction pattern. Subject of the present invention is that the investigation for only deviation from the normal diffraction pattern will allow rapid identification of the defects on periodic mask patterns. After the identification of the defects, these areas of interest can be analyzed in detail and the image can be reconstructed using ptychograhy.

There are several possible setups with ptychographic imaging for EUV. FIGS. 2 to 6 shows the possible setups. But other configurations are also possible.

FIG. 2 shows the simplest configuration for reflective imaging using scanning CDI. However, since the incidence angle is close to the surface normal, the collected angle by the detector is small if the part of the detector is not blocked. Therefore, our setups proposed in FIG. 2 are limited in resolution. The detector limited resolution is given as Resolution=lambda/(2*sin(incidence angle)) For actinic EUV mask inspection, the incidence angle is 6 degrees and therefore the best resolution that can be obtained by these setups is about 70 nm.

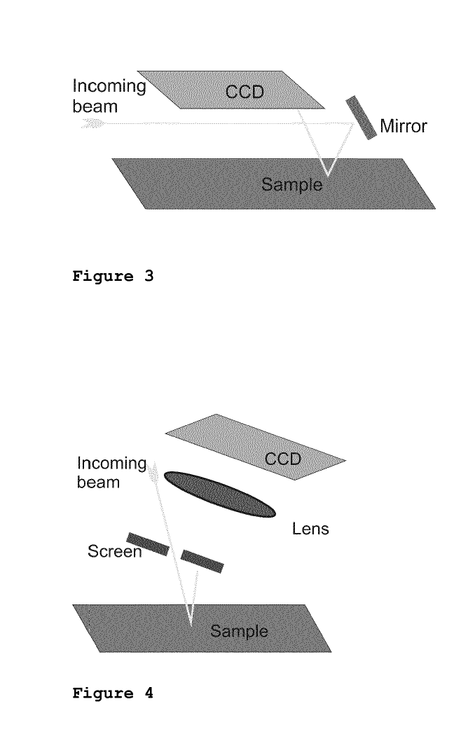

This problem is solved in the setups shown in FIGS. 3-6. FIG. 3 allows collection of half of the high-angle scattered light at 6 degrees of illumination.

In FIG. 4, the reflected light is detected by a fluorescent screen which converts the EUV light to visible light. The EUV light passes through a pinhole on the screen and reaches the sample. The diffracted intensity on the screen is detected by a pixel detector sensitive to visible light.

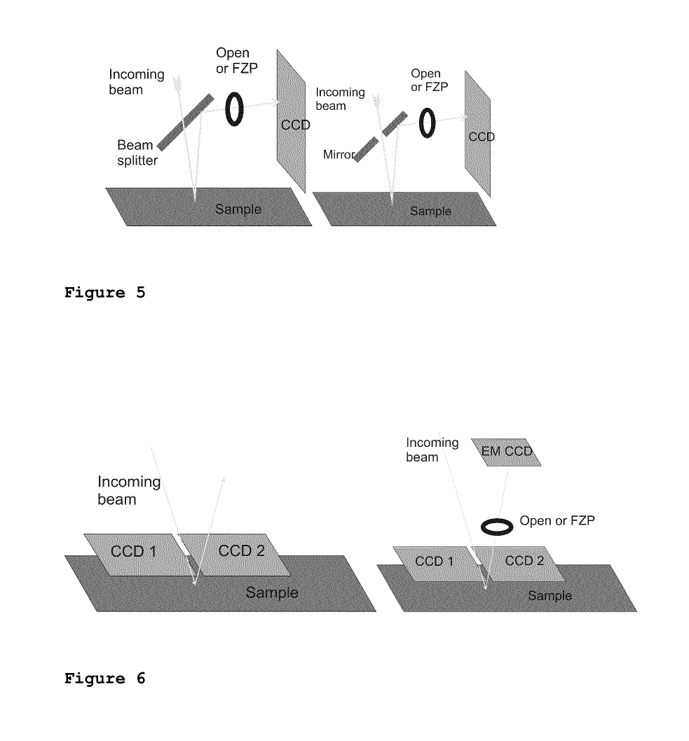

FIG. 5 shows different setups using beam splitters. First setup uses a beamsplitter which is partially transparent and partially reflective to light. Beamsplitter is used either to reflect the incoming light to the sample and transmit the light from the sample or to transmit the incoming light to sample and reflect the outgoing light from sample to detector. The other figure realizes the beamsplitting concept using a reflective mirror and a through pinhole on it to transmit the light or a reflective pinhole on a transparent film.

FIG. 5 also introduces the option of imaging with lens. This lens can be inserted and retracted. It can be used to obtain a low-resolution image, which can be used for navigation purposes or for faster reconstruction of the high resolution image using ptychographic methods combined with the a-priori low resolution image.

FIG. 6 shows, two setups for high-NA reflective imaging using scanning CDIs. In the first setup two detectors are used to capture the scattering intensity into high angles, enabling to reconstruct high-resolution images. Nevertheless, in this configuration low-angle scattering information is missing and therefore it may reduce the fidelity of reconstructed images. This problem is solved in the configuration where a third detector is placed to capture part of the low angle reflection. Here, also a lens can be employed to obtain a low resolution image for navigation or reconstruction purposes.

We note that in all the figures, CCD refers to any type of pixelated detector and not limited to soft X-ray CCDs.

We note that the methods and setups disclosed in this invention are also valid at other wavelengths such as BEUV and soft X-rays. The present invention therefore proposes a novel technique, which can be called very generally differential CDI. For periodically structured masks, a fast inspection can be executed by steps of multiples of period, which should give the same diffraction pattern. Subject of the present invention is that the investigation for only deviation from the normal diffraction pattern will allow rapid identification of the defects on periodic mask patterns. Compared to other CDI methods, a priori knowledge of the illumination is not needed. Both amplitude and phase are extracted whereas optics-based imaging requires through-focus imaging in order to reconstruct the phase.

### REFERENCES

[1] K. A. Goldberg and I. Mochi, JVST B, C6E1 (2010)

[2] K. A. Goldberg et al, JVST B 27, 2916 (2009)

[3] K. A. Goldberg et al, Proc. SPIE 7969, 796910 (2011)

[4] Jap. J. Appl. Phys. 49 06GD07-1 (2010)

[5] T. Harada et al, JVST B 27, 3203 (2009)

[6] J. Doh et al, J. Korean Physical Soc. 57, 1486 (2010)

[7] Sandberg et al, Optics Letters 34, 1618 (2009)

[8] S. Roy et al, Nature Photonics 5, 243 (2011)

1-2. (canceled)

3. A method for reflective and scanning coherent diffractive imaging for identifying errors in mask patterns and defects on mask blanks, the method comprising:
a) providing a set-up for scanning a mask in reflection mode with low and high numerical aperture;
b) illuminating the mask pattern with a extreme ultraviolet lithography light beam at an angle of 2 to 35°;
c) detecting a diffracted light beam with a position-sensitive detector;
d) analyzing intensities detected in the detecting step using ptychographic algorithms and thereby obtaining a high resolution image of the sample of arbitrary patterns; and
e) analyzing the detected intensities for intensity variations deviating from a normal intensity distribution caused by a periodic mask pattern in order to detect defects on the mask.

4. A system for differential coherent diffractive imaging for identifying errors in periodic mask patterns, comprising:
a) a ptychographic set-up for scanning the mask in reflection mode with low and/or high numerical aperture;
b) an extreme ultraviolet lithography light beam for illuminating the mask pattern at an angle of between 2 and 35°;
c) a position-sensitive detector for detecting a diffracted light beam; and
d) means for analyzing the detected intensities using ptychographic algorithms and thereby obtaining a high resolution image of the sample of arbitrary patterns; and
e) means for analyzing the detected intensities for intensity variations that deviate from a normal intensity distribution caused by the periodic mask pattern in order to detect defects on the mask.
